(19) United States
(12) Patent Application Publication
(10) Pub. No.: US 2012/0305893 A1
(43) Pub. Date: Dec. 6, 2012

(54) TRANSISTOR DEVICE

(75) Inventor: Jean-Pierre Colinge, Cork (IE)

(73) Assignee: University College Cork-National University of Ireland ,Cork, Cork City (IE)

(21) Appl. No.: 13/579,825

(22) PCT Filed: Feb. 21, 2011
(86) PCT No.: PCT/EP2011/052492

§ 371 Date: Aug. 17, 2012

Related U.S. Application Data
(60) Provisional application No. 61/306,367, filed on Feb. 19, 2010.

(51) Int. Cl. H01L 29/775; H01L 21/335

(52) U.S. Cl. 257/29; 438/142; 257/E29.245; 257/E21.4

(57) ABSTRACT

The invention provides transistor device comprising a source, a drain and a connecting channel, the channel is a nano-structure device adapted to allow current flow between the source and drain. The channel comprises an ultra-high doping concentration and is of the same polarity as in the source and/or drain. Essentially the transistor device of the present invention acts as a junctionless, highly-doped gated resistor. In the context of optimal performance of the transistor high doping means equal to or exceeds 1×10¹⁹ atom/cm³ results in that the device can operate as a junctionless transistor device.

### CROSS REFERENCE TO RELATED APPLICATIONS

This application claims the benefit of International Application No. PCT/EP2011/052492, filed on Feb. 21, 2011, which claims priority to U.S. Provisional Patent Application No. 61/306,367, filed on Feb. 19, 2010, which are incorporated by reference as if fully set forth.

### FIELD OF INVENTION

The invention relates to transistors, and in particular provides a new type of transistor based on a nano-scale architecture.

### BACKGROUND

A classical transistor is a solid-state active device that controls current flow. A transistor usually comprises a semiconducting material, such as silicon or germanium, in three electrode regions with two junctions. The regions are alternately doped positive-negative-positive or negative-positive-negative in a semiconducting sandwich.

All existing transistors are based on the formation of junctions. Junctions are capable of both blocking current and letting current flow, depending on the applied bias. Junctions are typically formed by putting in contact two semiconductor regions with opposite polarities. The most common junction is the PN junction, which consists of a contact between a P-type piece of silicon, rich in holes, and an N-type piece of silicon, rich in electrons. Every textbook on Semiconductor Device Physics contains a chapter on the classical PN Junction and is known by every engineering/physics student. Other types of junctions include the metal-silicon “Schottky” junction and the heterojunction, which is a PN junction comprising two types of semiconductor materials. The bipolar junction transistor contains two PN junctions, and so does the MOSFET. The JFET (Junction Field-Effect Transistor) has only one PN junction and the MESFET (Metal-Semiconductor Field-Effect Transistor) contains a Schottky junction.

Typically, all Metal Oxide Semiconductor (MOS) transistors are made using two junctions comprising a source junction and a drain junction. An n-channel transistor is a N-P-N structure. A p-channel transistor is a P-N-P structure. Trends in the electronic industry require smaller and smaller components resulting in transistor sizes down to the nano-scale. This trend has presented significant problems in the manufacture and reliable operation of these devices.

Over the past decades, the Metal Oxide Semiconductor Field Effect Transistor (MOSFET) has continually been scaled down in size; typical MOSFET channel lengths were once several micrometers, but modern integrated circuits are incorporating MOSFETs with channel lengths of less than a tenth of a micrometer. For example, Intel Corporation began production of a process featuring a 65 nm feature size (with the channel being even shorter) in early 2006. Until the late 1990s, this scaling resulted in great improvement in MOSFET circuit operation. Historically, the difficulties with decreasing the size of the MOSFET have been associated with the semiconductor device fabrication process, the need to use very low voltages, and with poorer electrical performance necessitating circuit redesign and innovation (small MOSFETs exhibit higher leakage currents, and lower output resistance, discussed below).

The semiconductor industry maintains a “roadmap”, the ITRS, describing forecasts and technology barriers to development for device sizes updated approximately annually. The 2006 roadmap estimated devices with a physical gate length of 13 nm in size by the year 2013.

Very small transistors have the problem that one has to form two junctions, namely a source and a drain junction that are separated by a region with doping different of that in the junctions. For example, N-type doping with a concentration of 10²⁰ atoms/cm³ is used in the source and drain and P-type doping with a concentration of 10¹⁷ to 10¹⁸ atoms/cm³ is typically used between the source and drain. The diffusion of source and drain doping atoms is difficult to control in very small transistors. In all transistors, the diffusion of source and drain impurities is a bottleneck to the fabrication of very short-channel devices, and very low thermal budget processing must be used. For example flash heating can be used to heat to very high temperatures for a short time period so as to minimise the length of time at elevated temperatures require expensive equipment and thus costly processing steps.

Very costly techniques are used to minimise this diffusion, but even in the absence of the diffusion the statistical variation of the impurity concentration can cause device parameter variation problems.

In Silicon-On-Insulator (SOI) structures and related structures (FinFETs, Multigate FETs, Pi-gate FETs, Omega-gate FETs, Gate-all-Around FETs), one can use an intrinsic channel region (undoped region instead of the P-type region). One can also use a channel region with the same doping type as the source and drain; the transistor is then an accumulation-mode device: N⁺-N-N⁺ for an n-channel device and P⁺-P-P⁺ for a p-channel transistor. See for example a paper entitled “Conduction mechanisms in thin-film, accumulation-mode p-channel SOI MOSFETs”, J P Colinge, IEEE-Trans on Electron. Dev., vol. 37, p. 718, 1990, or a paper entitled “Accumulation-mode Pi-gate MOSFET”, J. W. Park, W. Xiong, J. P. Colinge, Proceedings of the IEEE International SOI Conference, pp. 65-67, 2003 for further explanation.

Inversion-mode transistor devices are designed to operate on the following principle. In the ON state, the current flows in surface inversion channels. In the OFF state, current flow is blocked by a reverse-biased junction. This device needs to be made in a semiconductor, and metallic conductors such that highly-doped semiconductors cannot be used for the channel.

Accumulation-mode transistor devices operate on a different principle. In the ON state, most of the current (say 90-95%) flows in surface accumulation channels. A small portion of the current flows in the body of the device. This is explained in the paper referenced above. In the OFF state, current flow is blocked by depletion of carriers in the channel. This device needs to be made in a semiconductor, and metallic conductors such that highly-doped semiconductors cannot be used for the channel.

A junction-less transistor architecture has been proposed in US patent publication number US2008251862, Ashok et al., which discloses an accumulation-type transistor configuration implemented using silicon nanowires. However a problem with this device is that it does not operate well as a transistor because the low doping requirement in the channel imposes an equally low doping in the source and drain, which limits the current drive to low values. Increasing the doping in the source and drain would solve that problem, but then the device becomes a classical accumulation-mode transistor as described in “Accumulation-mode Pi-gate MOSFET”, J. W. Park, W. Xiong, J. P. Colinge, Proceedings of the IEEE International SOI Conference, pp. 65-67, 2003.

A further problem with accumulation-mode devices, made in “thick” silicon films (thicker than 20 nm), is that they exhibit worse short-channel characteristics because the channel (or the peak of carrier concentration in sub-threshold operation) is located further from the gate electrode than in “regular” (i.e. inversion-mode) transistors. This detrimental effect can be reduced when the silicon film is thinned down, as shown in the paper entitled “Investigation of Deep Submicron Single and Double Gate SOI MOSFETs in Accumulation Mode for Enhanced Performance”, E. Rauly, B. Iñiguez, D. Flandre, Electrochemical and Solid-State Letters, vol. 4 (3), pp. G28-G30 (2001).

In multigate MOSFETs with a small enough cross section, there is no difference in short-channel effects between accumulation and inversion-mode devices, as shown in the paper entitled “MultiGate SOI MOSFETs: Accumulation-Mode versus Enhancement-Mode”, A. Afzalian, D. Lederer, C. W. Lee, R. Yan, W. Xiong, C. Rinn Cleavelin, J P Colinge, IEEE 2008 Silicon Nanoelectronics Workshop, P1-6, Jun. 15-16, Honolulu, USA, 2008.

There is therefore a need to provide a transistor device structure and architecture to overcome the above mentioned problems.

### SUMMARY

According to the invention there is provided transistor device comprising a source, a drain and a connecting channel,

the channel is a nano-structure device adapted to allow current flow between the source and drain; characterised in that:

the channel comprises an ultra-high doping concentration and is of the same polarity as in the source and/or drain.

Essentially the transistor device of the present invention acts as a junctionless, highly-doped gated resistor. In the context of optimal performance of the transistor ultra-high doping means equal to or exceeds 1×10¹⁹ atom/cm³. Conventional teaching in the art of transistor design requires that doping concentrations should be kept much lower for a transistor. The inventor of the present invention discovered that by using nano-wire channels and doping at ultra high concentration levels the transistor can operate as a junctionless transistor device (i.e. same polarity in the source drain and channel) and perform the same as classical transistors.

In the ON state, all the current flows in neutral (un-depleted) material. The conduction path ranges a neutral “filament” between source and drain (near threshold) up the full section of the device (once neutral and under flatband conditions). In the OFF state, current flow is blocked by depletion of carriers in the channel, which is made possible by the small (nanoscale) cross section dimensions of the nanowire/nanoribbon in which the channel is made.

In one embodiment the channel is degenerately doped. Doping concentration above about 10¹⁸ atom/cm³ is considered degenerately doped at room temperature.

In one embodiment the ultra-high doped concentration channel is adapted to act like a quasi metallic channel.

The transistor device can be made in a heavily-doped semiconductor, which has metallic properties, as well as in metallic conductors provided that the field penetration depth is large enough to fully deplete the nanowire to turn it off. In effect, the high doping aspect allows the channel to act like a quasi metallic channel (due to exceptional large doping concentrations) and the possibility of making metal transistors that heretofore have never been proposed.

The transistor device of the present invention provides for CMOS operation of long-channel (1 micrometer) junctionless transistors made on N⁺ and P⁺ silicon nanowires that rival similar tri-gate inversion-mode devices. In contrast with accumulation-mode devices, the transistor devices are chosen to be fabricated with extremely high doping of the channels and equal doping in the channel and the source and drain regions. The devices can be fabricated on thin SOI nano-ribbons, 5-15 nm thick and 5-50 nm wide, for instance, heavily N⁺ or P⁺ doped to ensure a high on-current and good ohmic contacts but under the condition of enabling the full depletion of the nanowire body. In contrast with inversion-mode transistors, the gates for the n-type and p-type transistors are heavily doped P⁺ and N⁺, respectively, in order to achieve positive and negative operating threshold voltages, respectively.

In one embodiment the device is positioned on a bulk silicon substrate. The device is electrically isolated from the bulk silicon substrate and optionally comprises an insulator layer positioned below the interface between the channel and silicon substrate.

In one embodiment the doping concentration of a selected value can be used in the channel region and the source and drain extension regions. Optionally spacer technology can be adapted to be used to locally increase the outer source and drain regions to a concentration above the selected value.

In another embodiment of the present invention there is provided a channel device for use in a transistor to connect a source region and drain region, said channel comprising an ultra-high doping concentration.

In a further embodiment of the present invention there is provided a process for making a transistor device comprising the steps of:

arranging one or more nano-devices on a substrate, for example a silicon substrate;

implanting ultra high doping concentration in said nano-wire to define a channel region; and

depositing a gate material to cooperate with said one or more nano-wires, said gate material is adapted to control current flow through said channel region by applying a charge to the gate material.

The operating principle for a junctionless n-type accumulation device can be described in one embodiment as follows. In the on-state the whole nanowire body behaves as a conducting channel and the application of the drain voltage results in an on-current depending on the parameters (geometry, doping) of the thin film semiconducting resistor. When the gate voltage is decreased, the transistor body is gradually depleted at the off-state is reached when the conductive channel is pinched-off by the gate-controlled depletion region.

The transistor device according to the invention surprisingly achieves on/off current ratios of 10⁶ for a 1-volt gate voltage variation, with inverse subthreshold slopes close to the ideal MOSFET limit of 60 mV/decade at room temperature, which is the best performance to date in such device family. Note that in the subthreshold region (channel pinched-off by the depletion), the inverse sub-threshold stays limited to the value of kT/q*ln(10).

The advantages of the junctionless transistor devices, according to the invention, are (i) they intrinsically have better SCE, drain-induced barrier lowering (DIBL) and subthreshold slope degradation than inversion-mode devices when aggressively scaled down, (ii) because of the current flow in the middle of the channel a less degraded mobility is expected, (iii) their drain current in the on state is independent on the oxide capacitance, relaxing the gate dielectric scaling request and making their intrinsic delay time quasi-independent of the oxide thickness, in opposition with inversion-mode or accumulation-mode MOSFETs.

In a further embodiment there is provided a device, for example a transistor or gated resistor, comprising a first portion, a second portion and a connecting third portion,

the third portion is adapted, and controlled externally, to allow current flow between the first portion and the second portion;

the third portion comprises an ultra-high doping concentration and is of the same polarity as the first and/or second portion.

In another embodiment there is provided a metal junction-less transistor device comprising a source, a drain and a connecting channel, characterised in that:

the channel is a nano-structure device, controlled by a gate electrode, to allow current flow between the source and drain; and

the channel comprises a high doping concentration of the same polarity and same doping concentration as in the source and drain, wherein the gate electrode comprises means for varying a voltage to control the current flow between source and drain.

The invention provides for a revolutionary architecture of a new transistor, based on a new junctionless structure approach to what is otherwise known in the industry such as “accumulation mode” devices. This invention provides a junctionless transistor, in which the doping in the source and drain, and in between, is of the same type and the same dopant concentration. The result is that the transistor device of the present invention ensures that all dopant diffusion and statistical spread problems are eliminated. This greatly relaxes thermal budget constraints and facilitates processing. The doping concentration in the channel is heavier than in classical devices because it is the same as in the source and drain. A further advantage of having a junctionless transistor is that there is less electron reflections such that there is a better transmission of the current from source to derain.

The end product is a new type of transistor construction and presents an enormous market for the inventive transistor devices in this field. The applications of transistors in ICs are in memory and in microprocessors. For example, all AMD processors as well as the IBM/Toshiba/Sony Cell processors used in Playstation, X-Box, etc, which are made using SOI (Silicon-On-Insulator) processes, can directly benefit from the junctionless structure described here.

In one embodiment the channel is dimensioned to allow for full depletion of electron carriers across the channel. The key to fabricating a junctionless transistor (in other words a gated resistor) according to the invention is the formation of a semiconductor layer that is thin and narrow enough to allow for full depletion of carriers when the device is turned off. The semiconductor also needs to be heavily doped, of the order of 1×10¹⁹ atom/cm³ or greater, to allow for a decent amount of current flow when the device is turned on. To improve the ON/OFF ratio of the transistor the smaller dimension of the channel and the higher the doping is desirable. It will be appreciated that the source and drain are defined by the Gate length.

In one embodiment the transistor comprises means for applying a low gate voltage to provide a region depleted of electron carriers across the channel to keep the transistor in an OFF state.

In one embodiment the transistor comprises means for applying a high gate voltage to provide a region of electron carriers across the channel to keep the channel in an ON state.

In one embodiment the nano-structure device is a nano-wire or nano-ribbon device. It will be appreciated that the channel can be small enough in any dimension to allow for the depletion of electron carriers across the channel. In a particularly preferred embodiment the channel length and/or width is of the order of 10 nm or less.

In another embodiment of the present invention there is provided, a transistor comprising a source, a drain and a connecting channel, characterised in that the doping in the channel is of the same polarity as in the source and/or drain, and substantially of the same concentration as in the source and/or drain, such that diffusion effects between the source channel and drain are substantially eliminated. The diffusion is eliminated since diffusion occurs only if a gradient of concentration is present.

In another embodiment there is provided a multi-gate transistor structure comprising a plurality of transistors characterised in that each transistor comprises a source, a drain and a connecting channel, wherein the channel is a nano-structure device, controlled by a gate voltage, to allow current flow between source and drain; and the doping in the channel comprises the same polarity and same doping concentration as in the source and drain.

In one embodiment the multi-gate transistor structure comprises means for varying the gate voltage to control the current flow between source and drain.

Non-SOI devices such as the “bulk FinFET” device described in [K. Okano et al.: Process Integration Technology and Device Characteristics of CMOS FinFET on Bulk Silicon Substrate with Sub-10 nm Fin Width and 20 nm Gate Length. Technical Digest of IEDM, 725 (2005)] or the “body-tied FinFET” described in [Kyoung-Rok Han et al.: Design considerations of body-tied FinFETs (Omega-MOSFETs) implemented on bulk Si wafers, Journal of Semiconductor Technology and Science 4-1, 12 (2004)] can also be fabricated with a junctionless architecture, provided appropriate electrical isolation from the substrate is achieved.

In one embodiment the source and the drain comprise a N⁺⁺-N⁺-structure in which the N⁺ portion of the source (drain) is connected to the N⁺ channel to provide a junction-less device.

In one embodiment the source and the drain comprise a P⁺⁺-P⁺-structure in which the P⁺ portion of the source (drain) is connected to the P⁺ channel to provide a junction-less device.

Preferably, the doping concentration in the source and drain is approximately 1×10¹⁹ to 1×10²⁰ atom/cm³. It will be appreciated that the doping concentration depends on the cross-sectional dimensions of the channel. The doping decreases as the dimensions are increased, in order to allow for the gate potential to deplete the channel of carriers when the device is turned off.

The cross section of the channel is a section through the device that is perpendicular to the source-to-drain direction. The term “cross section dimensions” or “cross sectional dimensions” includes the “width” and the “height” or “thickness” of the semiconductor channel. It applies to devices such as FinFETs where the height is larger than the width, devices such as trigate transistors where the width is sensibly equal to the height, and nanoribbon devices where the width is larger than the thickness. It also applies to devices with a rounded or circular cross section and planar SOI devices which are essentially nanoribbon devices with a large width. Thus in a tall device with small width (e.g. FinFET), the cross section dimension is essentially equal to the width, in a planar SOI device the cross section dimension is essentially equal to the SOI film thickness, and in a cylindrical nanowire the cross section dimension is essentially equal to the diameter. The cross section must be small enough for the channel region to be depleted on carriers when a gate voltage is applied to turn the device off. The actual minimum cross dimension value is related to the channel doping concentration. Thus, the higher the doping concentration, the smaller the cross section required.

In another embodiment the junctionless transistor can be made using a planar device to provide a bulk planar junctionless transistor.

Suitably, the transistor is incorporated in a multi-gate FinFET, Tri-gate, Pi-gate, omega-gate or gate-all-around structure.

In one embodiment the junction-less transistor comprises use of spacer technology to locally increase the doping concentration in the source and drain regions outside the region of electrostatic influence of the gate. To cite an example, a doping concentration of 0.8×10²⁰ cm⁻³ can be used in the channel region and the source and drain regions (thereby forming a junction-less structure) and spacer technology can be used to locally increase the doping concentration in diffusion regions adjacent to the source and drain to a concentration above 10²⁰ cm⁻³.

It will be appreciated that all existing technology variations used in conventional semiconductor technology can be applied to the junctionless transistor in a straightforward manner. These include, but are not limited to: spacer technology, Silicide (or Salicide) formation, use of High-k dielectric materials, use of a metal gate, use of a TiN gate, use of strain technology, use of semiconductor materials such as Germanium, SiGe, SiGeC, III-V alloys, molybdenite, use of polycrystalline or amorphous semiconductors, use of semiconductors with grain boundaries or other localized charge trapping regions, use of charge-trapping dielectric layers (such as ONO and nanocrystal-containing oxides), use of nanowire transistors with non-uniform channel cross sections (e.g. with diameter constrictions). It will be appreciated that the transistor devices of the invention can make use of semi-metal (or metalloid) nanowires (e.g. Bismuth, tin, thallium, tellurium, selenium, antimony or alloys thereof) as a possible replacement to semiconductor nanowires.

In particular, spacer technology can be used to locally increase the doping concentration in the source and drain regions outside the region of electrostatic influence of the gate electrode. To cite an example, a doping concentration of 0.8×10²⁰ cm⁻³ can be used in the channel region and the source and drain extension regions (thereby forming a junctionless structure) and spacer technology can be used to locally increase the outer source and drain regions to a concentration above 10²⁰ cm⁻³.

In one embodiment the junctionless transistor of the present invention can be used to fabricate zero-capacitor random-access-memory (ZRAM) cells. Such a device can be programmed to a “0” or “1” logic state and retain the stored information for a finite amount of time.

### BRIEF DESCRIPTION OF THE DRAWINGS

The invention will be more clearly understood from the following description of an embodiment thereof, given by way of example only, with reference to the accompanying drawings, in which:

FIG. 1 illustrates a three-dimensional perspective view of a junctionless transistor according to the invention;

FIG. 2 illustrates a longitudinal cross section implementation of an N-type silicon junctionless transistor according to the invention;

FIG. 3 illustrates a longitudinal cross section implementation of a P-type silicon junctionless transistor according to the invention;

FIG. 4 is a number of views illustrating a sample operation of a N-type transistor according to the invention;

FIGS. 5A, 5B and 5C illustrate a number of 3D perspective views illustrating sample operation of the junctionless transistor;

FIG. 6 illustrates a three dimensional mesh model (trigate “nanowire” cross section) of the transistor according to the present invention;

FIG. 7 illustrates a three dimensional model of the potential distribution of the present invention (trigate “nanowire” cross section);

FIG. 8 illustrates a three dimensional model of the electron concentration of the present invention (trigate “nanowire” cross section);

FIG. 9 is a graph of the simulated transistor output characteristics of the present invention (trigate “nanowire” cross section);

FIG. 10 illustrates a cross section of a gate-all-round device showing examples of doping concentrations;

FIG. 11 illustrates the electron concentration in the transistor device when turned off (trigate “nanowire” cross section);

FIG. 12 illustrates a transmission electron microscopy image of a device (trigate “nanoribbon” cross section) according to the invention;

FIG. 13 illustrates the measured current as a function of gate voltage, both N-type and P-type devices are presented (trigate “nanoribbon” cross section);

FIG. 14 illustrates the measured current as a function of drain voltage (output characteristics) of an N-type device (trigate “nanoribbon” cross section);

FIG. 15 illustrates the measured current as a function of drain voltage (output characteristics) of a P-type device (trigate “nanoribbon” cross section);

FIG. 16 illustrates a junctionless transistor with extra doping introduced in the outer source and drain using spacer technology, the dotted line indicates the approximate position of the junction in a non-junctionless transistor;

FIG. 17 is an example of device implementation (longitudinal cross section): two N-type junctionless transistors in series with contacts;

FIG. 18 is a schematic circuit representation of the transistor arrangement of FIG. 17, a classical MOS transistor symbol is used to represent the junctionless device, for convenience;

FIGS. 19 to 23 illustrate different embodiments of the transistor device on a bulk semiconductor substrate;

FIG. 19 shows the transistor device on a bulk semiconductor substrate using a trigate (triple-gate) architecture;

FIG. 20 shows an N-channel and a P-channel device on a bulk semiconductor substrate using a trigate (triple-gate) architecture;

FIG. 21 shows an N-channel and a P-channel device on a bulk semiconductor substrate using a pi-gate architecture;

FIG. 22 shows the devices of FIG. 21 integrated on a common bulk semiconductor substrate;

FIG. 23 shows a plurality of devices with pi-gate architecture integrated on a common bulk semiconductor substrate;

FIG. 24 is a schematic diagram of a bulk multi-gate MOSFET with pi-gate architecture;

FIG. 25 illustrates subthreshold characteristics of bulk multi-gate device at drain bias (V_{ds}) of 1 V for different gate lengths (L_{g});

FIG. 26 illustrates the DIBL (drain-induced barrier lowering) and subthreshold slope (S-slope) of bulk multi-gate device for various gate lengths (L_{g}). S-slope was extracted at V_{ds}=1 V;

FIG. 27 shows the cut-plane of the total current density through the middle of heavily-doped semiconductor channel;

FIG. 28 illustrates the intrinsic device delay time for a MOSFET and for gated resistors;

FIG. 29 illustrates the difference between carrier (electrons) distribution in an inversion, an accumulation mode devices and a junctionless device in the ON state;

FIG. 30 shows the device tested for capacitor-less memory operation;

FIG. 31 shows another embodiment for the device according to the invention where the channel is of the same type and with substantially the same doping concentration as the source and drain; and

FIG. 32 illustrates simulation results obtained for a Bulk Junctionless Transistor (BJT) and an inversion-mode (N⁺⁺⁺-P-N⁺⁺⁺) device.

### DETAILED DESCRIPTION OF THE PREFERRED EMBODIMENTS

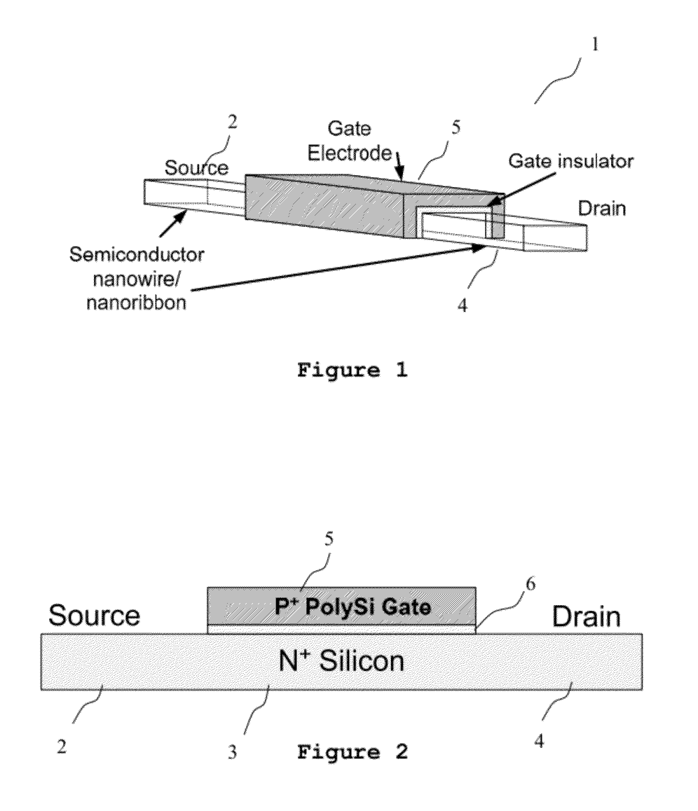

Referring now to the drawings, and initially FIGS. 1 to 4, FIG. 1 illustrates a three-dimensional perspective view of a junctionless transistor according to the invention indicated generally by the reference numeral 1. The underlying insulator layer (buried oxide) is not shown. A semiconductor nanowire structure, for example a nanowire or nanoribbon, forms a source 2, channel 3 and drain 4, partially surrounded by a gate electrode 5. The source 2 and drain 4 are the portions of the semiconductor nanowire that are not covered by the gate electrode 5. A small layer of gate insulator 6 can be provided between the gate electrode 5 and the channel 3. In a classical MOSFET they are defined by junctions, but this is not the case in the junctionless transistor device of the invention.

In a classical MOSFET the junctions are situated underneath the edges of the gate (or very close to the edges of the gate, depending on processing parameters). In a similar way, the invention defines the boundary between the source and the channel region of the junctionless transistor as the portion of the semiconductor situated underneath the edge of the gate or in its immediate vicinity. Similarly, the invention defines the boundary between the drain and the channel region of the junctionless transistor as the portion of the semiconductor situated underneath the other edge of the gate or in its immediate vicinity. It will be appreciated that the device been symmetrical the source and drain can be interchanged.

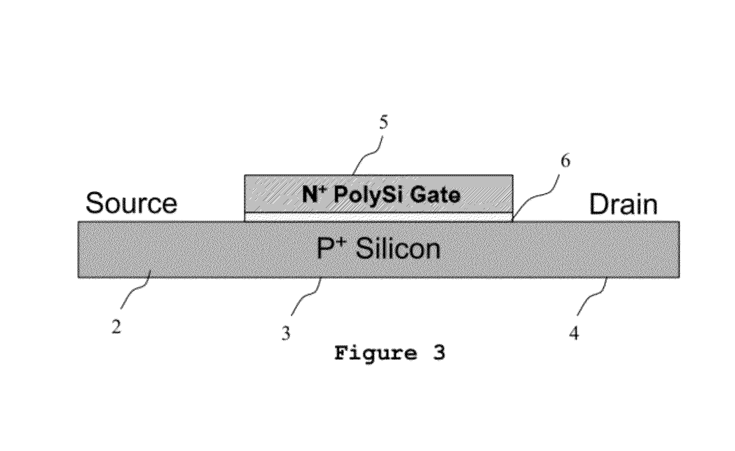

In an N-channel (N-type) device, as shown in FIG. 2 the distinction is that the source 2 is the at a lower potential than the drain 4. In a P-type device, as shown in FIG. 3, the source 2 is at a higher potential than the drain 4.

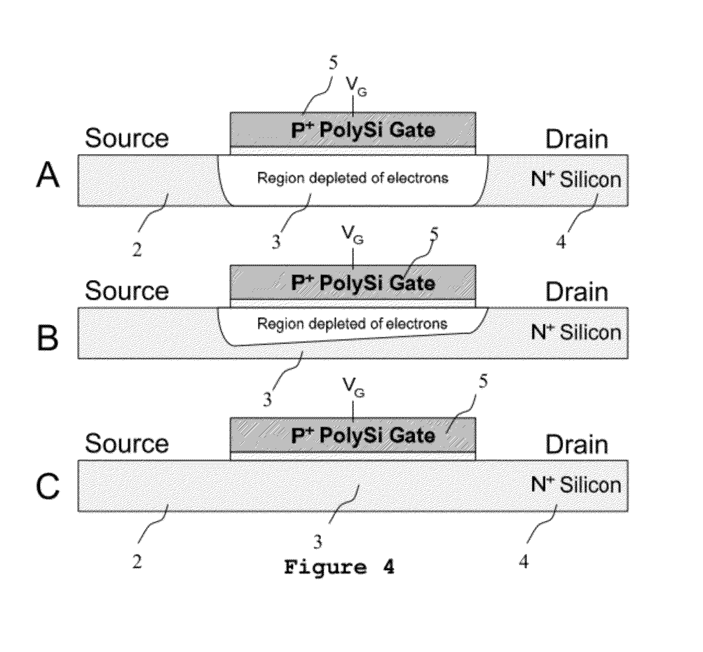

FIG. 4 is a number of views illustrating a sample operation of a N-type transistor according to the invention. How the device works (example of an N-type device) with V_{G}(A)<V_{G}(B)<V_{G}(C) is as follows:

A: For a low gate voltage, for example 0V, the channel region 3 under the gate 5 is depleted of carriers and no current can flow between source 2 and drain 4. The device is effectively in an OFF state.

B: For a higher gate voltage, for example 0.4V, the channel region 3 under the gate 5 is partially depleted of carrier and some current can flow between source 2 and drain 4.

C: For a still higher gate voltage, for example 1V the region under the gate 5 is no longer depleted of carrier and can flow between source 2 and drain 4. The device is an ON state.

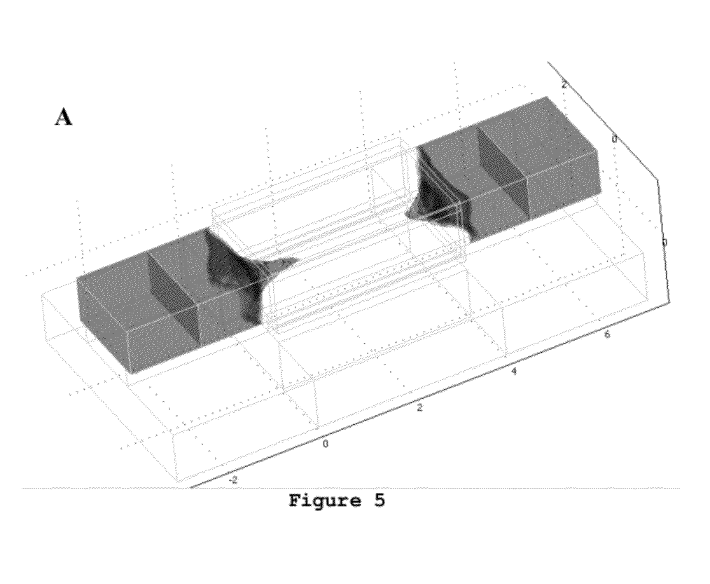

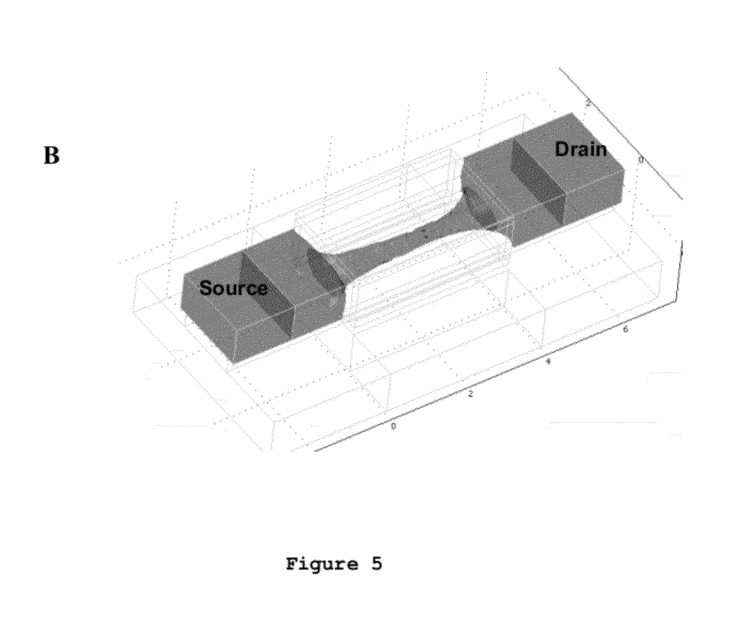

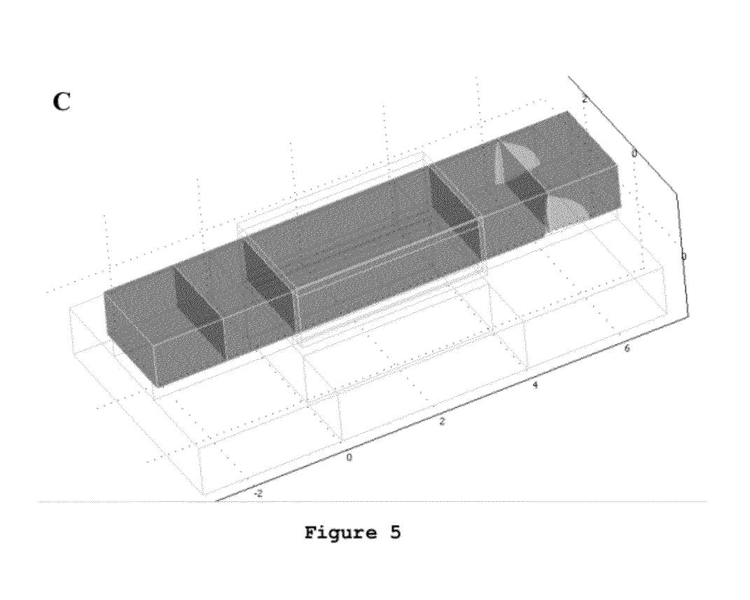

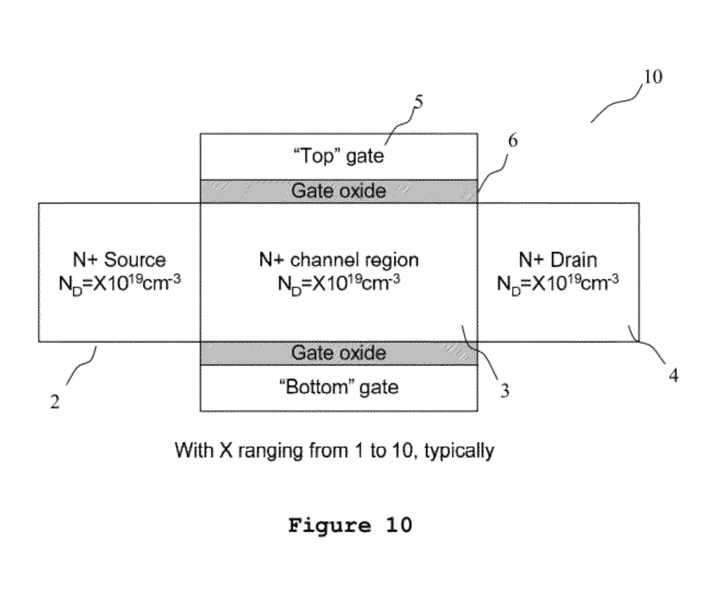

It will be appreciated that current can be further increased if gate voltage is increased beyond V_{G}(C) through an increase of the electron concentration in the region underneath the gate. FIGS. 5A, B and C illustrate a number of three dimensional perspective views equivalent to FIGS. 4A, B and C to clearly show the electron flow distribution when different gate voltages are applied. It will be appreciated that if the gate 5 is dimensioned substantially around the channel (gate-all-around, for example as shown in FIGS. 10 to 12 below) greater control for the depletion of electrons can be achieved. In the simulation shown in FIG. 5 the following parameters were used: Channel length: 40 nanometres, Width of nanowire/nanoribbon: 20 nanometres, Height (thickness of nanowire): 10 nanometres and Doping concentration: N-type, 1e19 cm−3. As the gate voltage is varied the channel region 3 becomes depleted of electrons, similar to a ‘pinching’ or ‘squeezing’ effect when pressure is applied to a conduit with water flowing through it, such that electron flow is reduced until finally the channel is fully depleted of electrons to prevent further electron flow. The transistor is then in an OFF state.

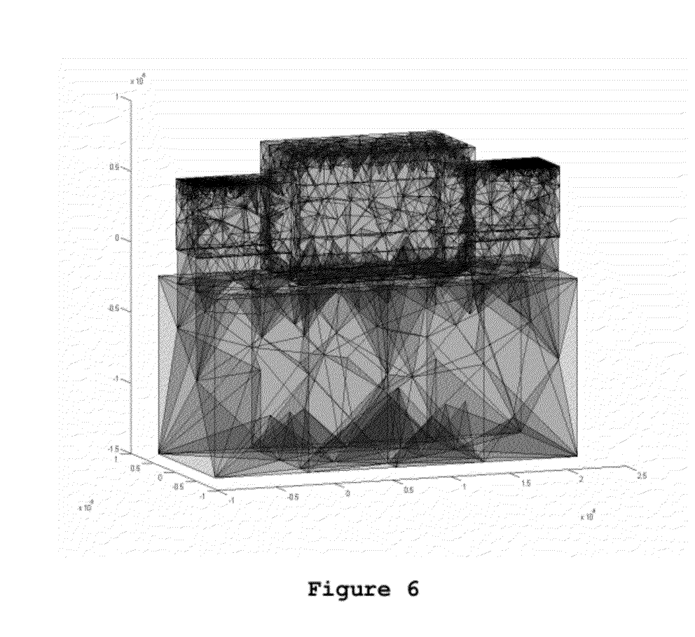

FIG. 6 shows a three dimensional mesh model of a junction-less transistor, according to the present invention. The doping in the source and drain and in between (in the channel) is of the same type, and of the same concentration. The simulated structure comprises Silicon thickness: Wₛᵢ=5 nm; Silicon width: tₛᵢ=5 nm; gate oxide thickness: Tₒₓ=2 nm: Channel length: L=15 nm; doping concentration: N_{D}=8e19 cm⁻³.

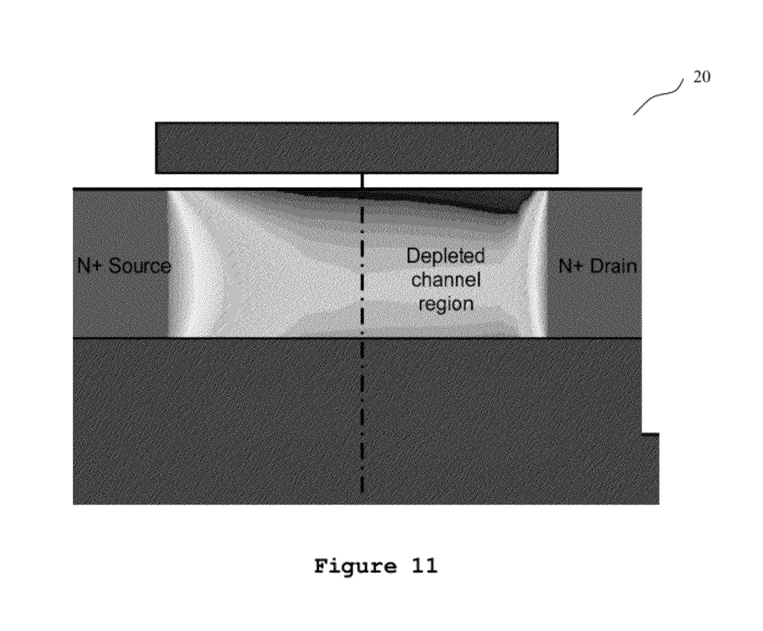

Various different parameters can be used for the present invention, for example, an N-type doping with a concentration of 8×10¹⁹ atoms/cm³ is used in the source and drain and a N-type doping with a concentration of 8×10¹⁹ atoms/cm³ is used between the source and drain (i.e. “X”=8 in FIGS. 5 and 11. Optionally a P-type doping with a concentration of 8×10¹⁹ atoms/cm³ is used in the source and drain and a P-type doping with a concentration of 8×10¹⁹ atoms/cm³ is used between the source and drain. The inventive device provides the channel being of the same type and same concentration, such that all diffusion and statistical spread problems are eliminated. In other words, the doping used in the junction-less transistor device is of the same polarity (i.e. N or P) and the same concentration for source drain and connecting channel. The high doping concentration of the channel is selected to dramatically improve the performance of the transistor.

Here, the invention provides for the fabrication an N⁺-N⁺-N⁺ (or P⁺-P⁺-P⁺) device, where the doping concentration in the channel is comparable to that in the source and drain. Since the gradient of doping concentration between source and channel or drain and channel is very small, little or no diffusion can take place, which eliminates the need for costly ultrafast annealing techniques and allows one to fabricate devices with shorter channels.

A key point for such a device to operate properly is to fabricate it in a multi-gate (FinFET, Tri-gate, Pi-gate, omega-gate, gate-all-around) structure with sufficiently small width or cross section. In order to be able to turn the transistor device off, one must be able to deplete the channel region of its carriers (electrons in the case of an N⁺-N⁺-N⁺ device). Junction-less transistor operation is achievable in a ‘classical’ (i.e. single-gate) SOI device, but in that case the silicon film thickness needs to be in the order of a few nanometres to be able to turn the current off. In a multi-gate architecture, the gate potential is able to deplete the channel from different sides, which allows one to use larger channel cross-sectional dimensions (thickness and/or width) than in a single-gate configuration. This is much easier to fabricate reproducibly.

A transistor device with a 10 nm×10 nm cross section and a doping concentration of 3×10¹⁹ cm⁻³ can be turned off by the gate and operate correctly as a MOS transistor. Such a transistor device is immune to doping diffusion effects, and, because the ultra high doping concentration in the channel, to random doping fluctuation effects. The ultra high doping concentration is essential for operation of the invention.

A preferred embodiment of the present invention is to provide triple-gate transistors, which can be manufactured using SOI processes. It will be appreciated that the writing of critical dimension levels (silicon islands and gate levels) can be made, for example, using an e-beam lithography machine. The e-beam lithography machine is capable of writing patterns with dimensions down to nano-scale. A mix and match approach can be used and non-critical levels can be written using conventional optical lithography. Oxidation and etching techniques, resist ashing techniques, hydrogen anneal or chemical etching e.g. in an ammonia solution can be used to reduce the cross-section of nanowire dimensions smaller than lines printed by the e-beam writer.

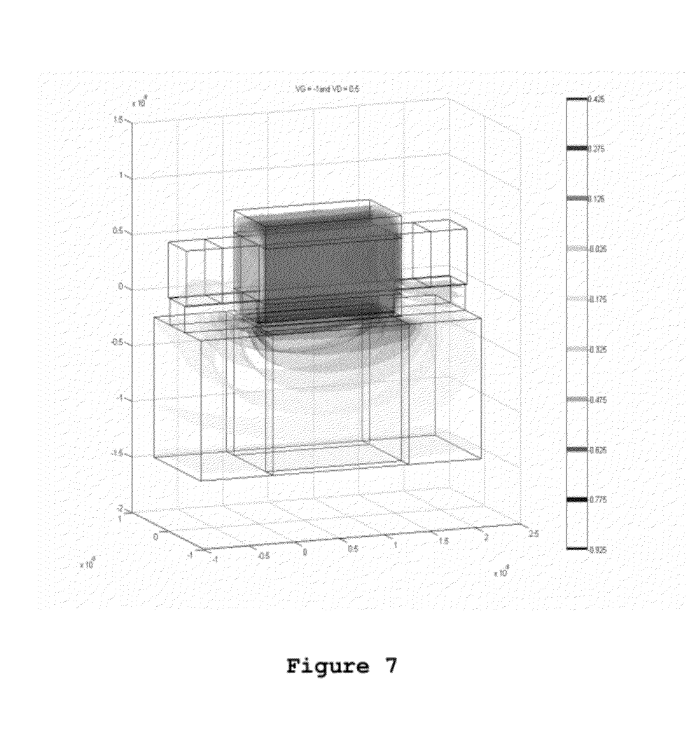

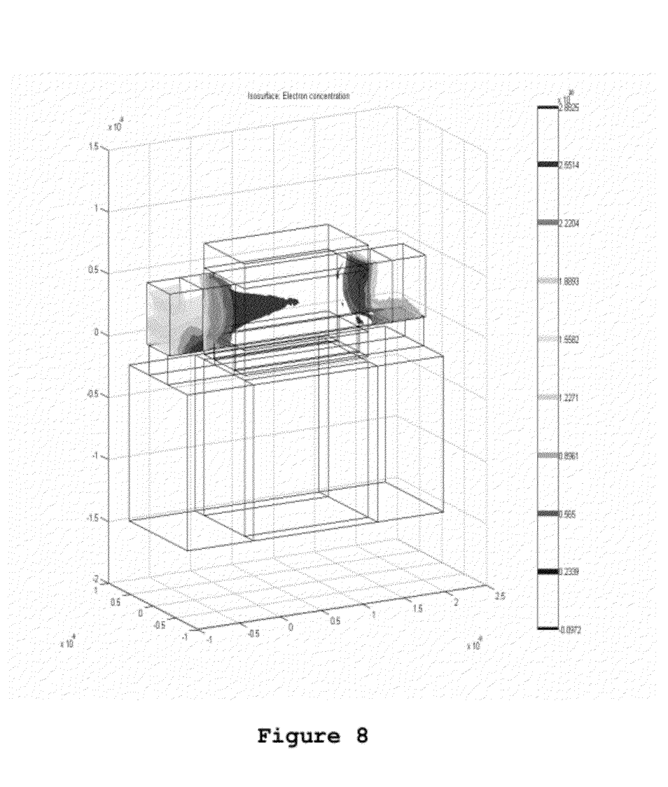

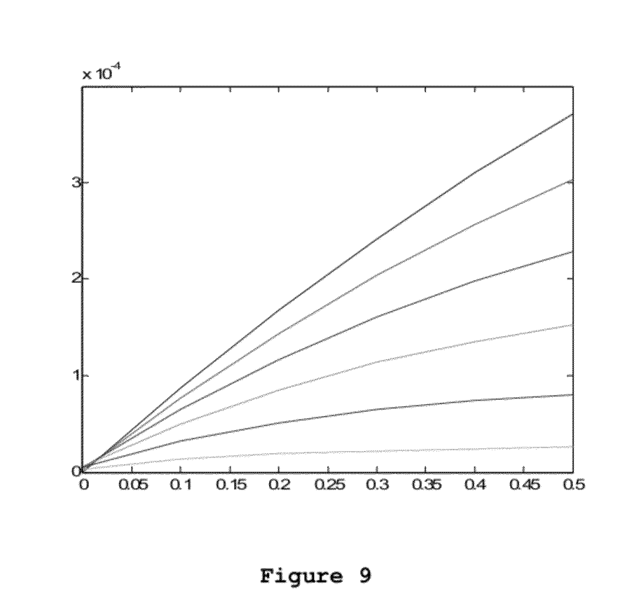

FIGS. 7, 8 and 9 illustrate the potential distribution, electron concentration and output characteristics of the transistor of the present invention and confirm that the transistor device operates as a regular transistor and can be turned off. FIG. 7 is a potential contour plot: Silicon thickness: Wₛᵢ=5 nm; Silicon width: tₛᵢ=5 nm; gate oxide thickness: Tₒₓ=2 nm: Channel length: L=15 nm; doping concentration: N_{D}=8e19 cm⁻³; Gate voltage: V_{G}=−1V; drain Voltage: 0.5V. FIG. 8 is an Electron concentration contour plot: Silicon thickness: Wₛᵢ=5 nm; Silicon width: tₛᵢ=5 nm; gate oxide thickness: Tₒₓ=2 nm: Channel length: L=15 nm; doping concentration: N_{D}=8e19 cm⁻³; Gate voltage: V_{G}=−1V; drain Voltage: 0.5V. FIG. 9 illustrates output characteristics (drain current vs. drain voltage); Silicon thickness: wₛᵢ=5 nm; Silicon width: tₛᵢ=5 nm; gate oxide thickness: Tₒₓ=2 nm: Channel length: L=15 nm; doping concentration: N_{D}=8e19 cm⁻³; Gate voltage: V_{G}=0:0.1:1V; drain Voltage 0→0.5V.

Referring to FIGS. 10 and 11, FIG. 10 illustrates a cross section (gate-all-around device), indicated generally by the reference numeral 10, showing examples of doping concentrations in order to bring the invention into effect. It will be appreciated that the value of ‘X’ shown, that represents the doping concentration, can be different in the source, channel or drain regions depending on the application required. In order words the doping concentration can vary between source, channel and drain, but the junctionless device will operate so long as the three regions are of the same polarity and that ultra-high doping concentration is present in the channel. Note that the source 2 channel 3 and drain 4 are of the same N polarity. FIG. 11 illustrates the electron concentration in a cross section of the device when it is turned off, indicated generally by the reference numeral 20. The transistor device shown is a pi-gate MOSFET. The dark shaded N+ Source and N+ Drain represent high electron concentration (equal to the source and drain doping concentration), the lighter shading represents a lower electron concentration.

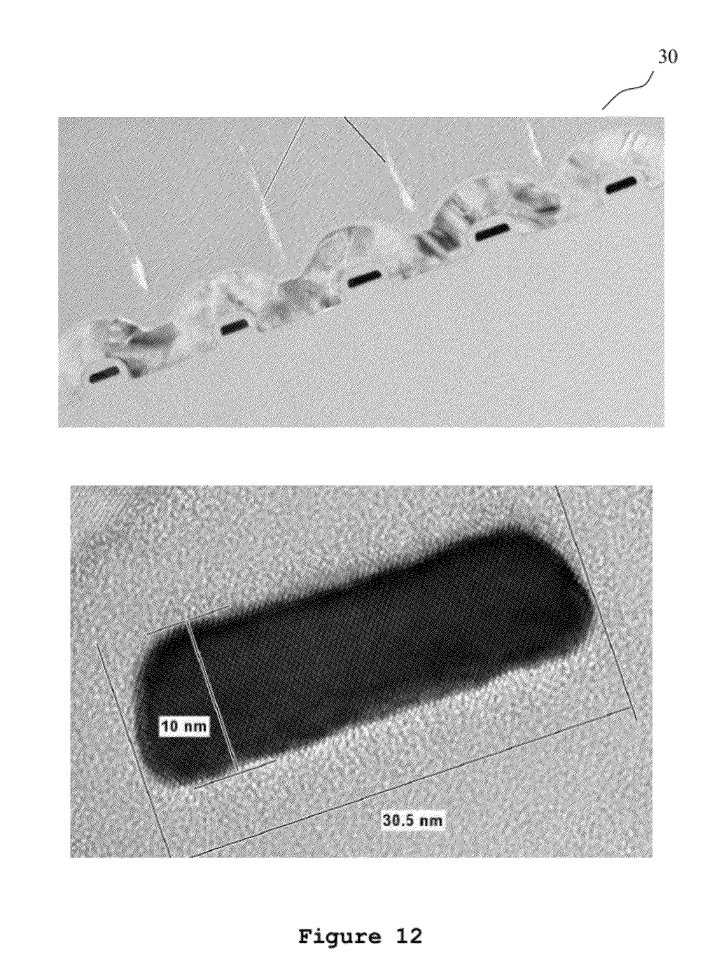

FIG. 12 shows the transmission electron microscopy image of a fabricated transistor device with a trigate “nanoribbon” cross section of 10 nm×30.5 nm according to the invention, indicated generally by the reference numeral 30. The top view shows a transmission Electron Micrograph of five parallel silicon gated resistor nanoribbons with a common polysilicon gate electrode. The nano-ribbon provides the source channel and drain as described above. The bottom view is a magnification of a single nanoribbon device. Individual atomic rows can be seen in the silicon.

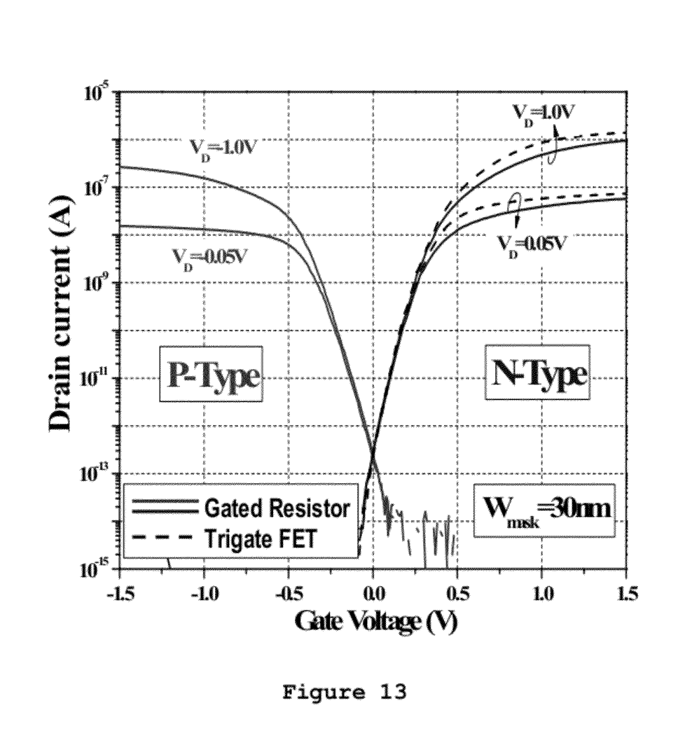

FIG. 13 illustrates the measured current as a function of gate voltage in the fabricated device illustrated in FIG. 12, for a measured I_{D}(V_{G}) of N- and P-channel trigate nanoribbon devices. L=1 um, W=20 nm. Both N-type and P-type devices are presented. For example the N-type curve shows that between 0V and 1V the ON/OFF current ratio is larger than 100,000,000, which is as high as in transistors with junctions. These measurements are highly significant as it shows that the transistor device fabricated shown in FIG. 12 can be turned ON and OFF properly using small voltages.

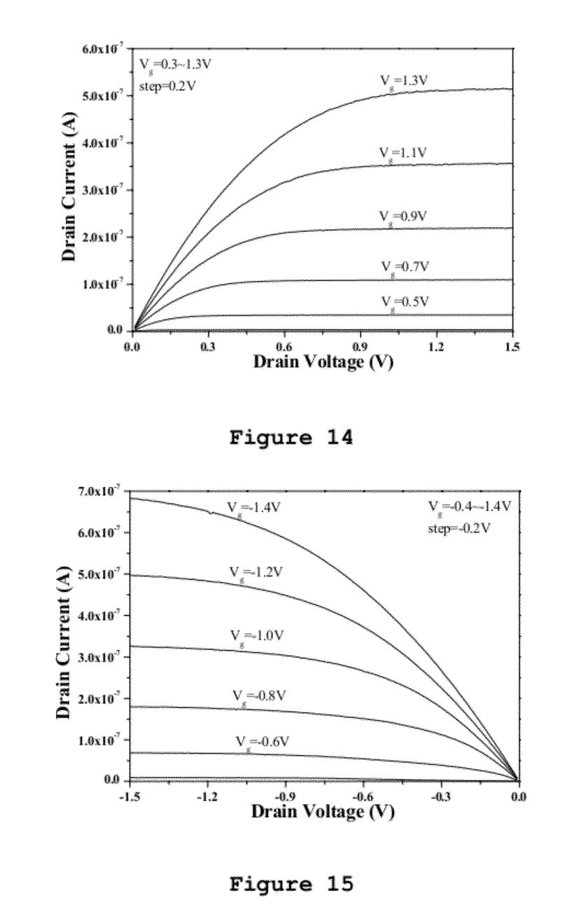

FIG. 14 illustrates the measured current as a function of drain voltage (output characteristics) of a fabricated N-type device with a trigate “nanoribbon” cross section of 10 nm×30 nm. FIG. 15 illustrates the measured current as a function of drain voltage (output characteristics) of a P-type device with a trigate “nanoribbon” cross section of 10 nm×30 nm.

In the context of the present invention a gate voltage has been described to control the region for the depletion of electrons in the channel. It will be appreciated that other control means can be used to control the gate electrode, for example current control or any form of electrostatic control.

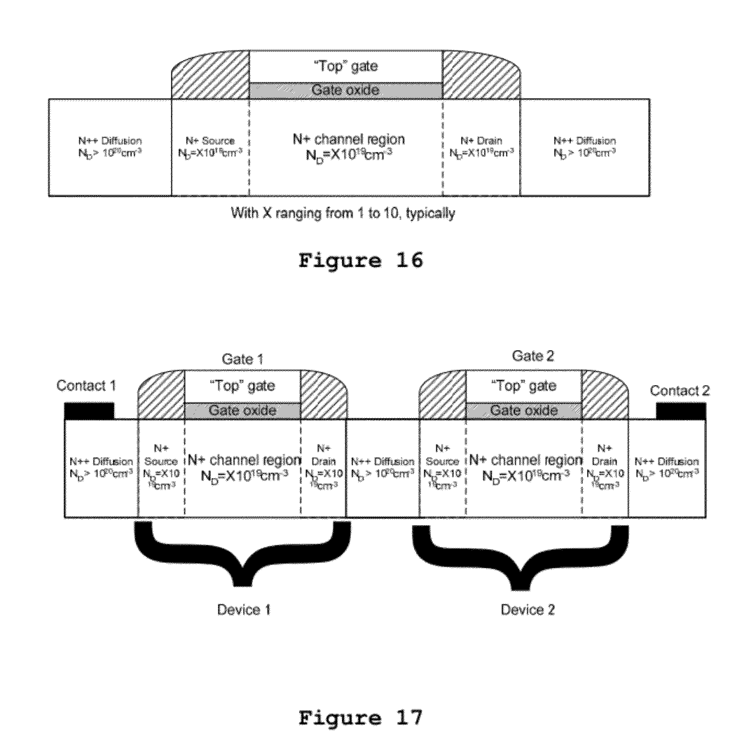

FIG. 16 illustrates an alternative embodiment of the present invention where a junctionless transistor with extra doping introduced in the outer source and drain using spacer technology is shown. The dotted line indicates the approximate position of the junction in a non-junctionless transistor. Again as with FIG. 10 above the value of ‘X’ can be a different value in the source, channel or drain regions depending on the application required.

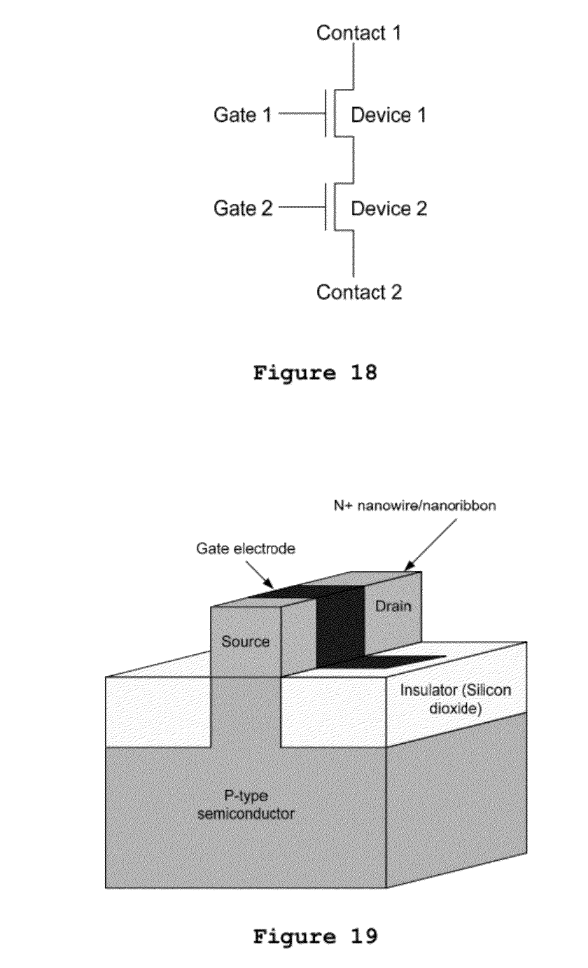

FIG. 17 is an example of a device implementation (longitudinal cross section) of a two N-type junctionless transistors in series with contacts (FIG. 16 shows a single junctionless transistor). FIG. 18 is a schematic circuit representation of the transistor arrangement of FIG. 17, a classical MOS transistor symbol is used to represent the junctionless device for convenience.

Another advantage of using a device with a heavily-doped channel region is that fluctuations of electrical parameters due to dopant fluctuations are reduced. In classical ‘large’ devices, the number of doping atoms in the channel is large (say 1000 impurity atoms) such that small statistical fluctuations of this number (say 998 atoms in one device and 1002 in another one) does not induce significant fluctuations of the electrical parameters (a ±0.4% fluctuation in the present case).

In nanometer-scale devices, doping fluctuations become a huge problem since, for example, the channel of a device with a 10 nm×10 nm silicon cross section and a 20 nm gate length doped with a concentration of 10¹⁸ cm⁻³ contains an average of only 2 doping atoms per cubic centimetre. The slightest statistical variation will bring the number of doping atoms to 1 or 3 (instead of 2), which represents a 50% variation. This has a high impact on the fluctuation of the electrical characteristics from device to device. Even “undoped” channels contain a doping concentration in the order of 10¹⁵ cm⁻³, which means that most of the devices will be undoped, but one device in 2000 will statistically contain a doping atom and, therefore, have different electrical properties than the 1999 other devices. This effect has been analysed in the paper entitled “Doping Fluctuation Effects in Trigate SOI MOSFETs”, Ran Yan, Aryan Afzalian, Dimitri Lederer, Chi-Woo Lee, and Jean-Pierre Colinge, Proceeding 4th EuroSOI Workshop, pp. 63-64, 2008.

In the junction-less device of the present invention, the channel is heavily doped (around several 10¹⁹ cm⁻³). As a result, a device with a 10 nm×10 nm silicon cross section and a 20 nm gate length statistically contains 40 doping atoms if the doping concentration is 2×10¹⁹ cm⁻³. Fluctuations of that number (say between 39 and 41 atoms) induce fluctuations of only ±2.5% of the doping concentration, which is much lower than in a device with “regular” channel doping. This is highly desirable and provides one of the main advantages of the present invention.

It will be appreciated that the use of spacer technology to locally increase the doping concentration in the source and drain regions outside the region of electrostatic influence of the gate electrode in the transistor. To cite an example, a doping concentration of 0.8×10²⁰ cm⁻³ can be used in the channel region and the source and drain regions (thereby forming a junctionless structure) and spacer technology can be used to locally increase the doping concentration in diffusion regions adjacent to the source and drain to a concentration above 10²⁰ cm⁻³.

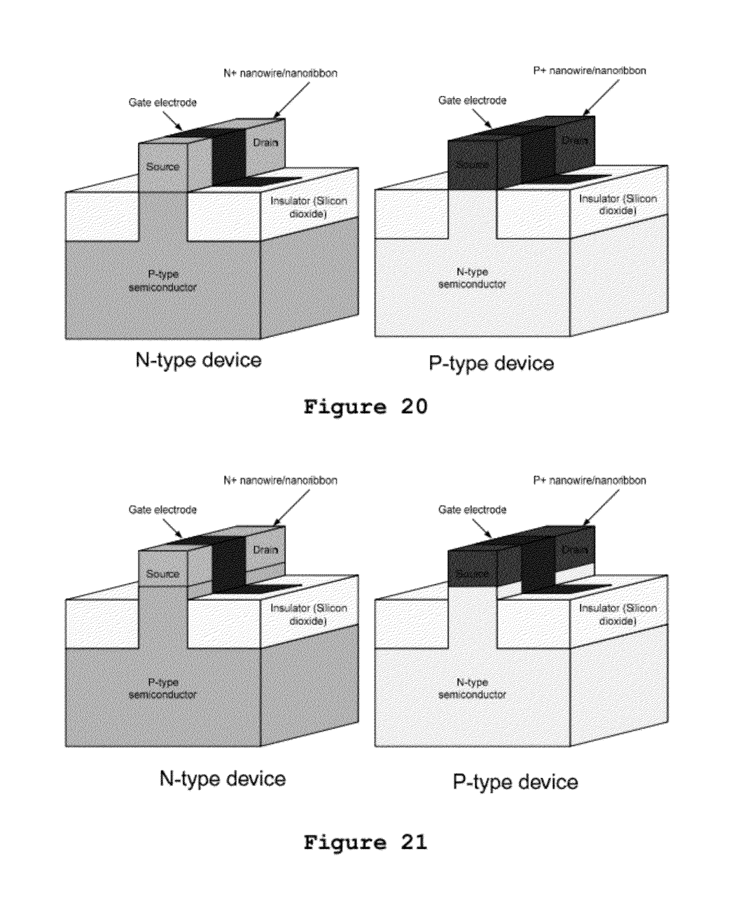

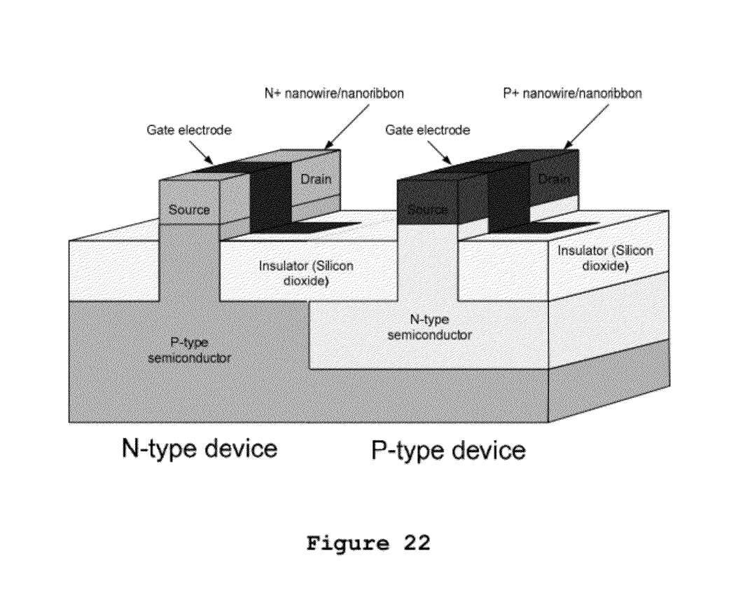

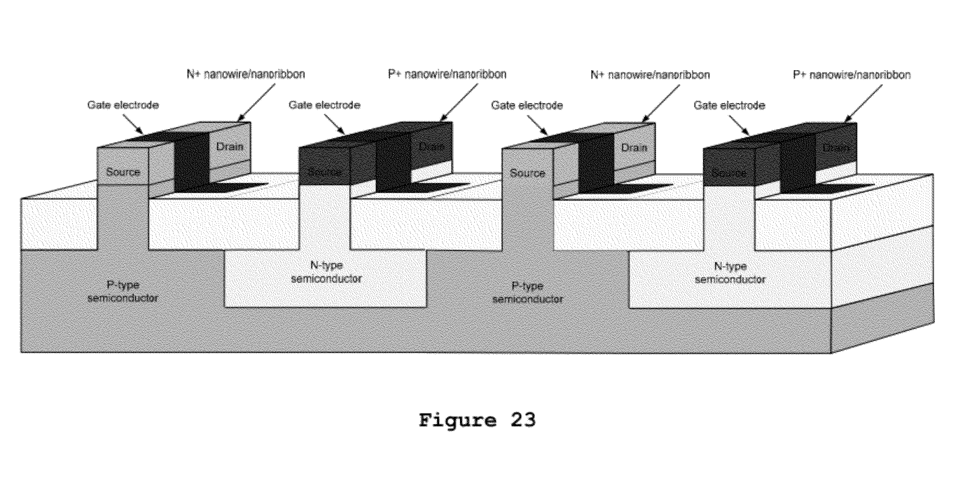

It will be further appreciated that the inventive transistor device can be made using a Silicon on Insulator (SOI) process. In addition other types of fabrication processes for manufacturing a transistor can also be used in order to make the transistor, according to the invention: non-SOI devices such as the “bulk FinFET” device described in [K. Okano et al.: Process Integration Technology and Device Characteristics of CMOS FinFET on Bulk Silicon Substrate with Sub-10 nm Fin Width and 20 nm Gate Length. Technical Digest of IEDM, 725 (2005)] or the “body-tied FinFET” described in [Kyoung-Rok Han et al.: Design considerations of body-tied FinFETs (MOSFETs) implemented on bulk Si wafers, Journal of Semiconductor Technology and Science 4-1, 12 (2004)] can also be fabricated with a junctionless architecture, provided appropriate electrical isolation from the substrate is achieved. In such a bulk implementation the semiconductor nanowire in which the device is fabricated is laying not on an insulator but on a semiconductor substrate such as silicon (sometimes in the industry referred to as bulk Si substrate). The electrical isolation between the device is provides by a PN junction (homojunction or heterojunction) and/or the combination of a PN junction and insulation layers (see FIGS. 19, 20, 21, 22 and 23). The transistor is still intrinsically junctionless in the direction of current flow but it is electrically isolated from the substrate by a junction. This is illustrated in FIGS. 19-24 where the transistor device of the present invention can be positioned to operate on top of a bulk Silicon substrate.

It is envisaged in another embodiment of the insulator level (such as silicon dioxide) can be below the interface between the heavily-doped nanowire and the silicon substrate as illustrated in FIGS. 21 to 23.

It will be further appreciated that the junctionless transistor device of the present invention can be made from any suitable type of semiconductor material such as, and not limited to, Germanium, SiGe, SiGeC, III-V alloys, polycrystalline semiconductors, etc. In another embodiment, the concept of a bulk multi-gate metal-oxide-semiconductor (MOS) device without lateral source/drain (S/D) junctions is proposed. The device is made in a heavily doped thin and narrow silicon nanowire, which allows full depletion by gate, thereby resulting in low leakage currents (˜10 pA) at very short gate lengths. The carriers flow through the central highly doped N⁺ region thereby experiencing reduced scattering and lower electric field perpendicular to current flow. As the proposed device has no lateral S/D junctions, it presents improved electrical characteristics along with simpler fabrication in bulk Silicon technology.

Lateral doping gradient or abruptness of source/drain (S/D) extension regions, a key process/device parameter, significantly impacts the S/D series resistance as well as short-channel effect (SCE) in nanoscale MOS devices and is a crucial technological factor affecting device scaling into the nanoscale regime. This unavoidable lateral doping-diffusion gradient of the S/D extension regions (along the channel) gives rise to current crowding at the vicinity of the channel end, leading to non-negligible spreading resistance components in total S/D external resistance with CMOS channel-length scaling. As steepness of S/D doping gradient depends on thermal budget and diffusivity, very small values of ˜3 nm/decade or lower may be difficult to achieve as it may ultimately require control of individual atoms and require non-standard process such as solid phase epitaxy or laser thermal annealing.

In order to overcome the technological problems in the formation of ultra-sharp S/D extension regions, the junctionless device of the present invention overcomes these problems. The junctionless transistor makes use of substantially the same doping in the S/D and channel regions circumvent the necessity to controlling S/D gradients in the extension regions near the gate edge. All the junctionless transistors described above were made on SOI wafers.

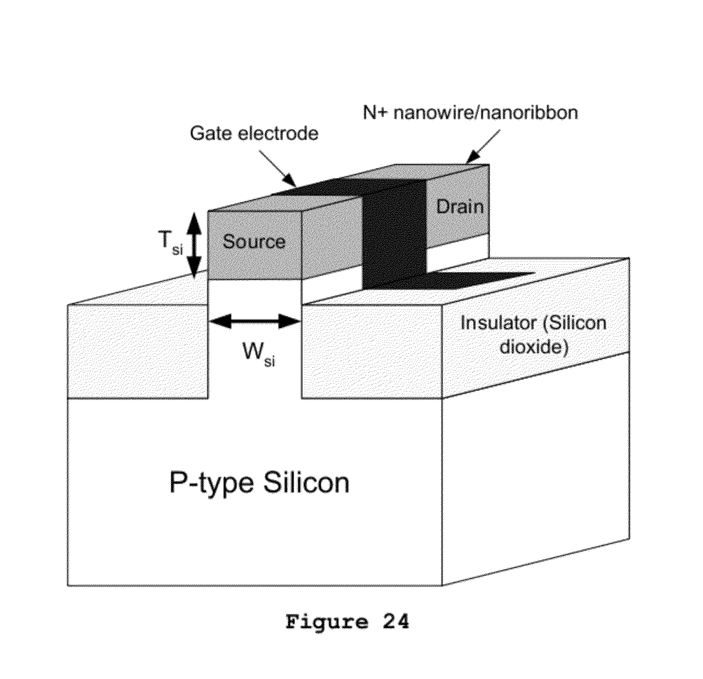

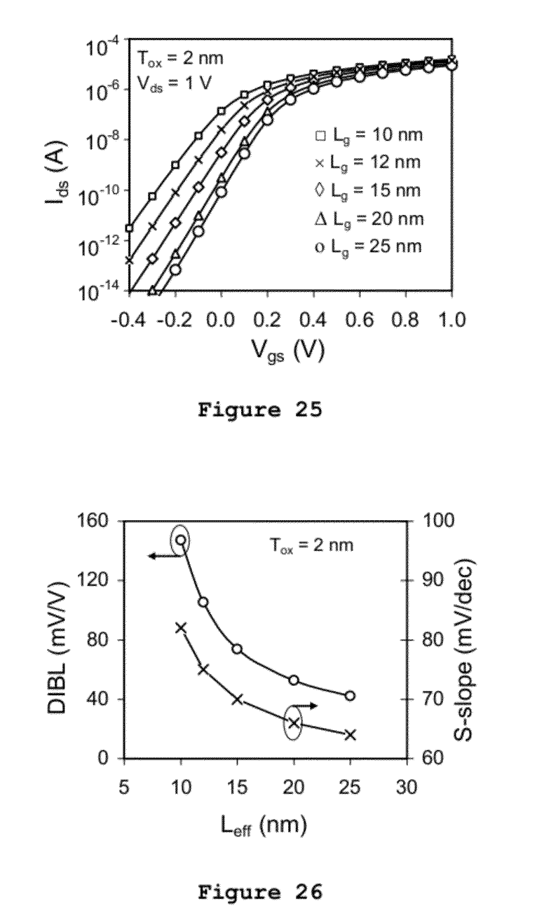

In another embodiment of the present invention there is provided a multi-gate junctionless MOSFET made on bulk silicon, in an approach similar to the fabrication of “bulk FinFETs”. This type of design on a bulk silicon would be of interest for transistor/chip manufacturers such as Intel Corporation. The device of the present invention exhibits excellent short-channel characteristics down to a gate length of 10 nm. As the device is junctionless from source to drain, the structure can be referred to as a bulk-JLMOSFET (bulk-JunctionLess MOSFET) in the following embodiment. Bulk multi-gate JLMOS devices were analyzed using 3D simulations, as shown in FIG. 24, the cross-section (Wₛᵢ×Tₛᵢ) of the N⁺-N⁺-N⁺ devices is 5×5 nm². The extension, d, of side gates into the moderately doped (10¹⁷ cm⁻³) p-type region was optimized to control SCEs and leakage current. Due to the N⁺-N⁺-N⁺ design of MOSFET no lateral S/D junction (along the current flow path) is formed and no diffusion of the source and drain impurity atoms in the channel takes place, which relaxes the processing thermal budget and the need for developing ultra fast annealing techniques. Although N⁺ region is highly doped (for example 9×10¹⁹ cm⁻³) to allow for high current flow in the on-state, the small cross-section of bulk-JMOS ensures full depletion resulting in low leakage current down to 10 nm devices as demonstrated in FIG. 25. The bulk JLMOSFET requires a metal gate with high work function such as P⁺ poly or platinum to control the threshold voltage. It should be noted that the leakage current of ˜10 pA can be achieved in 10 nm bulk JMOSFET and full device functionality is observed even in the absence of reversed biased lateral pn-junctions.

FIG. 26 shows the dependence of Subthreshold slope (S-slope) and Drain Induced Barrier Lowering (DIBL) parameters for bulk-JMOS device. Sub-threshold slope and DIBL can be limited to less than 80 mV/decade and 100 mV/V, respectively, in bulk-JMOS devices even with relatively thick gate oxide thickness of 2 nm at drain bias (V_{DS}) of 1 V for gate lengths down to 12 nm. DIBL was extracted as difference in threshold voltages for drain bias of 50 mV and 1V. An inversion mode intrinsic bulk MOSFET designed with buried ground plane (Nₐ˜10¹⁹ cm⁻³) and ‘idealized’ abrupt S/D junction with L_{g}=15 nm achieves a degraded S-slope of 78 mV/dec and DIBL of 95 mV/V when compared to 70 mV/dec and 74 mV/V respectively, for JMOSFET with same gate length. The S-slope and DIBL parameter for inversion mode devices can be reduced by adopting an underlap channel architecture. However, such an approach will require precise control of S/D doping gradient in the S/D extension regions and additional process complexity which will be extremely difficult to optimize and be an added source of variability in the nanoscale regime. Bulk-JMOS device offers greater flexibility in selecting device parameters to limit SCEs along with simpler fabrication process.

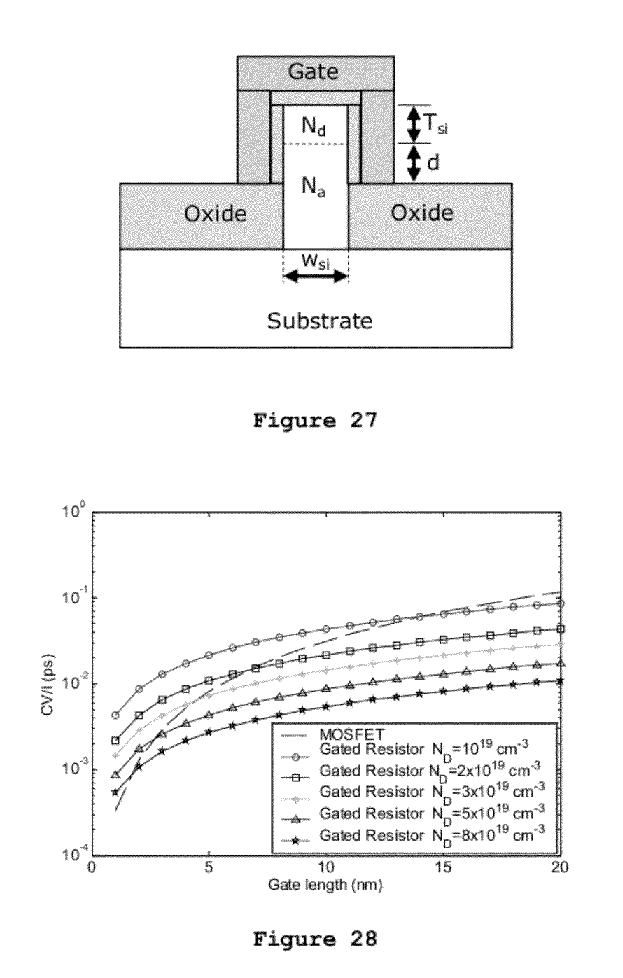

FIG. 27 shows the cut-plane of the total current density through the middle of silicon channel at a gate bias of 0.4 V. The dominant current flow is through the N⁺ region where the current density is the highest and not through the moderately doped p-type region or substrate. As the current flow is through the centre of silicon film and not at the Si—SiO₂ interface, carriers observe a reduced electric field in the direction perpendicular to flow and carriers travel through the film with higher mobility which is much less influenced by surface roughness scattering as experienced by bulk inversion mode transistors. This gives JLMOS transistors an advantage in terms of current drive for nanoscale applications.

In summary, the concept of a multi-gate MOSFET without any lateral source/drain junctions in bulk Silicon technology is provided for the first time. It has been demonstrated that JLMOSFET can exhibit low leakage currents and excellent short channel behaviour at shorter gate lengths. As the current flow is through the centre of silicon film, JLMOS devices offer lower electric field and reduced interface roughness scattering.

### An Extremely Simple Transistor Fabrication Process

It will be appreciated that Silicon-on-Insulator (SOI) technology can be used to produce high-quality single-crystal silicon films with a thickness of a few nanometers. Using commercial SOI wafers and electron-beam lithography, silicon nanowires (or nanoribbons) a few tens of nanometer wide and ten nanometers thick can be defined. After growing a 10-nm gate oxide, the nanowires were uniformly doped by ion implantation, using arsenic to dope the n-type devices and BF₂ to dope the p-type devices. The implant energies and doses were chosen to yield uniform doping concentrations ranging from of 2×10¹⁹ atoms cm⁻³ to 5×10¹⁹ atoms cm⁻³ in different wafers. Such high doping levels are traditionally reserved for source and drain extension formation in CMOS devices. In the gated resistor, high doping is required to ensure a high current drive and good source and drain contact resistance; it also imposes the use of nanowire geometries small enough to allow for the full depletion of the channel region, which is necessary to turn the device off. The gate was formed by deposition of a 50 nm-thick layer of amorphous silicon at a temperature of 550 C. in an LPCVD reactor. After heavy P⁺ or N⁺ gate doping using boron or arsenic ions at a dose of 2×10¹⁴ cm⁻², the samples were annealed in a nitrogen ambient at 900 C for 30 minutes to activate the doping impurities and transform the amorphous silicon gate material in polycrystalline silicon. The gate electrodes were then patterned and etched in a reactive ion etch (RIE) reactor. FIG. 12 shows a Transmission Electron Micrograph of five parallel silicon gated resistor nanoribbons with common polysilicon gate electrode. The magnified view of a single nanoribbon device is also shown, in which individual silicon atomic rows can be seen. To obtain desirable values for the threshold voltage, a P⁺ polysilicon gate is used for the n-type device and an N⁺ polysilicon gate is used for the p-channel device. After gate patterning, a protective SiO₂ layer was deposited, contact holes were etched and a classical TiW—aluminium metallization process can be used to provide electrical contact to the devices. No doping step was performed after gate patterning, leaving the source and drain terminals with exactly the same doping type and concentration as the channel region. The device has a multigate (trigate (or pi-gate or omega-gate) to be more specific) gate configuration, which means that the gate electrode is wrapped along three edges of the device (left, top and right sides of the nanoribbon). Classical trigate FETs were fabricated on separate wafers for comparison purposes. The fabrication process was identical to that used for the gated resistors with the following exceptions: the channel region was either left undoped of was P-type doped to a concentration of 2×10¹⁷ cm⁻³ (consider here n-channel devices), N⁺ polysilicon was used as gate material, and arsenic ions were implanted at a dose of 2×10¹⁴ cm⁻² with an energy of 15 keV after gate patterning to form the source and drain junctions.

Electrical Characteristics that Rival Those of the Best MOS Transistors

The current-voltage characteristics of the gated resistor are remarkably identical to those of a regular MOSFET. FIG. 13 shows the drain current, I_{D}, vs. gate voltage, V_{G}, for a drain voltage of ±1V in N-type and P-type devices having a width of 30 nanometers and a length of one micrometer. The off current is below the detection limit of the measurement system (10⁻¹⁵ A), and the on/off current ratio for between V_{G}=0 and V_{G}=±1V is larger than 10⁶. This clearly establishes the fact that turning off the device by electrostatically depleting the channel of carriers works as well as turning it off using a reverse-biased junction. FIG. 14 shows the experimental output characteristics of gated resistors. These characteristics are strikingly the same to those of regular MOSFETs.

The subthreshold slope, SS, is defined as the inverse of the slope of the log of the drain current vs. gate voltage below threshold. It is expressed in millivolts per decade (mV/dec) and represents the sharpness of the on-to-off switching of a transistor. It has a theoretical lower (best) value of

$$S S = \frac{{k}_{B} T}{q} ln ( 10 ) ,$$

corresponding to the numerical value of 60 mV/dec at T=300K. Typical bulk MOS transistors have a subthreshold slope on the order of 80 mV/dec and the best trigate SOI transistors come close to the theoretical limit with SS values of 63 mV/dec. The gated resistors reported here have a measured subthreshold slope of 64 mV/dec at 300K and remain within a few percents the ideal value of

$$\frac{{k}_{B} T}{q} ln ( 10 )$$

for temperatures ranging from 225K to 475K.

Traditional MOSFETs are constituted of a semiconductor sandwich that is either N⁺PN⁺ (N⁺ source, P-type channel region and N⁺ drain) for n-channel devices and P⁺NP⁺ for n-channel devices. In those devices, current flow between source and drain takes place in an inversion channel (n-type channel in P-type silicon or p-type channel in N-type silicon). In SOI, and in particular when using the trigate architecture, it is possible to realise accumulation-mode MOSFETs. Traditional accumulation-mode devices are constituted of a an N⁺NN⁺ sandwich (N⁺ source, N-type channel region and N⁺ drain) for n-channel devices and P⁺PP⁺ for p-channel devices. In an accumulation-mode device, the channel is of the same polarity as the semiconductor region in which it is formed. In that regard, junctionless gated resistors of the present invention are cousins to accumulation-mode devices. There is one important difference, however. The channel region of accumulation-mode MOSFETs is lightly doped and, therefore, has a high resistance. To drive significant current trough the device, a sufficiently large gate voltage must be applied to create an accumulation layer in the silicon beneath the gate oxide. This accumulation layer contains a high carrier concentration, which creates a low-resistivity path between source and drain and allows for significant current drive to flow. Inversion and accumulation carriers behave similarly in that they are confined to a very thin layer “squeezed” along the silicon/gate oxide interface by the electric field originating from the gate electrode. The carriers are scattered by the non-zero roughness of the silicon/oxide interface and by the presence of charges trapped in the oxide or at the semiconductor interface. Scattering increases with applied gate voltage, which reduces carrier mobility, and hence, drain current.

In a gated resistor, on the other hand, the channel region is neutral in the centre of the nanowire, and, the carriers being located in neutral silicon (i.e. not depleted silicon), they see a zero electric field in the directions perpendicular to the current flow. When the device is fully turned on, assuming a low drain voltage for simplicity, the entire channel region is neutral and in flat band conditions. The channel then basically behaves as a resistor with conductivity σ=qμN_{D}, and the mobility is that of carriers travelling through bulk silicon. The mobility of electrons in heavily doped N-type silicon is approximately 100 cm²/Vs; it varies very little for doping concentrations ranging from 10¹⁹ to 10²⁰ cm⁻² In a similar way, hole mobility hovers around 40 cm²/Vs in P-type silicon for the same doping concentrations. These mobility values may seem rather low, but they are to be placed in the context of modern short-channel MOSFETs. In unstrained silicon, the effective channel mobility of bulk MOSFETs drops from 400 cm²/Vs at the 0.8 m node to 100 cm²/Vs at the 0.13 m node. Similarly, a drop of peak mobility from 300 to 140 cm²/Vs is reported in FinFETs when the gate length is reduced from 0.9 m to 0.11 m. If it was not for straining techniques, the electron mobility at the 45 nm node would be well below 100 cm²/Vs. These straining techniques can, of course, be applied to gated resistors as well as they are applied to inversion-mode transistors.

In a MOSFFET, carriers are confined in an inversion channel in which scattering events increase quickly with gate voltage, thereby decreasing transconductance and current drive. In the heavily doped gated resistor, the drain current essentially flows through the entire section of the nanoribbon, instead of being confined in a surface channel. FIG. 5 shows the electron concentration in an n-type junctionless gated resistor for different values of gate voltage ranging from device pinch-off (FIG. 5a) to flatband conditions (FIG. 5c). The conduction path is clearly located near the centre of the nanowire, and not at the silicon-SiO₂ interfaces. This allows for the electrons to move through the silicon with bulk mobility, which is much less influenced by scattering than the surface mobility experienced by regular transistors. It is, however, possible to create surface accumulation channels by increasing the gate voltage beyond the flat-band voltage, if further increase of drain current is desired. Because it operates under bulk conduction rather than channel conduction, the gated resistor sees its transconductance degrade much more slowly when gate voltage is increased. As a result, higher current, and, therefore, higher speed performance, can be expected from the gated resistor.

The variation of threshold voltage of a gated resistor with temperature is similar to that of a bulk MOSFET, with values of approximately −1.5 mV/° C. measured in the transistor device. Interestingly, the decrease of mobility with temperature is much smaller in the gated resistors than in trigate FETs. In a lightly-doped FET the mobility suffers little from impurity scattering and tends to be phonon-limited and, therefore, shows a strong temperature dependence. In the highly-doped gated resistor, on the other hand, mobility is limited by impurity scattering rather by phonon scattering, and its variation of temperature is much smaller. For instance the electron mobility measured at room temperature in trigate FETs and gated resistors is 300 and 100 cm²/Vs, respectively. When heated to 200° C., the trigate FETs show a 36% loss of mobility, while the gated resistor sees its mobility reduced by only 6%.

### Perspectives for CMOS Logic Incorporating Junctionless Transistor:

Even though the electrical characteristics of the gated resistor are extremely similar to those of a regular MOS transistor, there is a fundamental difference between the two devices. MOSFETs (including FinFETs and trigate FETs) are normally-off devices, as the drain junction is reverse biased and blocks any current flow if no channel is created between source and drain. To turn the device on, the gate voltage is increased in order to create an inversion channel. The drain current in such a device is classically given by:

$${I}_{D} \approx μ {C}_{ox} \frac{{W}_{si}}{L} {( {V}_{DD} - {V}_{TH} )}^{2}$$

where Wₛᵢ is the width of the device, L is the gate length, V_{DD} is the supply voltage and Cₒₓ is the gate oxide capacitance. The capacitance of the gate electrode, C, is given by: C≈CₒₓWₛᵢL and the intrinsic delay time of the device, τ, is given by:

$$τ = \frac{CV}{I} \approx \frac{{C}_{ox} {W}_{si} {LV}_{DD}}{μ {C}_{ox} \frac{{W}_{si}}{L} {( {V}_{DD} - {V}_{TH} )}^{2}} \approx \frac{{L}^{2}}{μ {V}_{DD}}$$

Thus, speed performance can be increased by either reducing gate length or increasing mobility. Hence the use of strain silicon to boost the performances of MOSFETs. It is interesting to note that z is independent of the gate oxide thickness, as any increase of current—and thus an increase of speed—brought about by a reduction of the EOT is exactly matched by an increase of C, which slows the device down.

The gated resistor, on the other hand, is basically a normally-on device where the work function difference between the gate electrode and the silicon nanowire shifts the flatband voltage and the threshold voltage to positive values. When the device is turned on and in flatband conditions, it basically behaves as a resistor and the drain current is given by:

$${I}_{D} \approx q μ {N}_{D} \frac{{T}_{si} {W}_{si}}{L} {V}_{DD}$$

where Tₛᵢ is the thickness of the silicon and N_{D} is the doping concentration. Note that the current is independent of the gate oxide capacitance. Current can be increased simply by increasing the doping concentration of the device. The capacitance of the gate electrode is the same as in a regular MOSFET, and thus the intrinsic delay time is given by:

$$\frac{CV}{I} \approx \frac{{C}_{ox} {W}_{si} {LV}_{DD}}{q μ {N}_{D} \frac{{T}_{si} {W}_{si}}{L} {V}_{DD}} \approx \frac{{C}_{ox} {L}^{2}}{q μ {N}_{D} {T}_{si}}$$

In sharp contrast to the regular MOSFET, τ decreases when EOT is increased in a gated resistor. As a result, it is not necessary to reduce gate oxide thickness as much as in a MOSFET to increase performance. FIG. 28 shows the intrinsic delay time, τ, in a MOSFET and in gated resistors, as a function of gate length. The effective gate oxide thickness, EOT, is equal to 1 nm for all gated resistors, and one assumes Tₛᵢ=L. One can clearly see the increase of performance brought about by increasing the doping concentration in the gated resistor.

The variability of threshold voltage is larger in gated resistors than in traditional ultrathin-film, inversion-mode SOI transistors. Simulations indicate a dV_{TH}/dT_{Si} of 80 mV/nm in devices with a doping concentration of 1×10¹⁹ cm⁻³ and an EOT of 2 nm, which is approximately twice the variation observed in lightly-doped, ultrathin inversion-mode SOI devices. Since thin-film SOI wafers with a σT_{Si} of less than 0.2 nm can nowadays be produced, threshold voltage variations on the order of σV_{TH}=20 mV can be expected at wafer level.

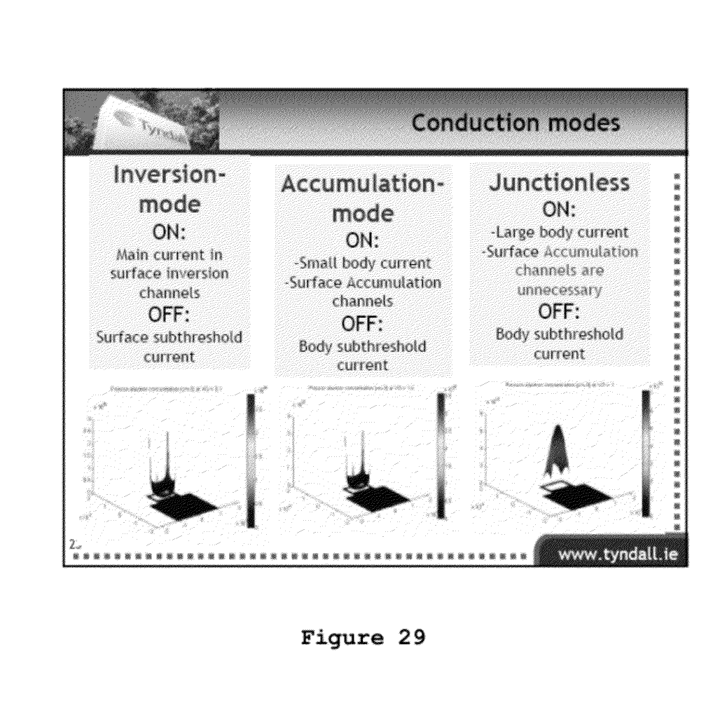

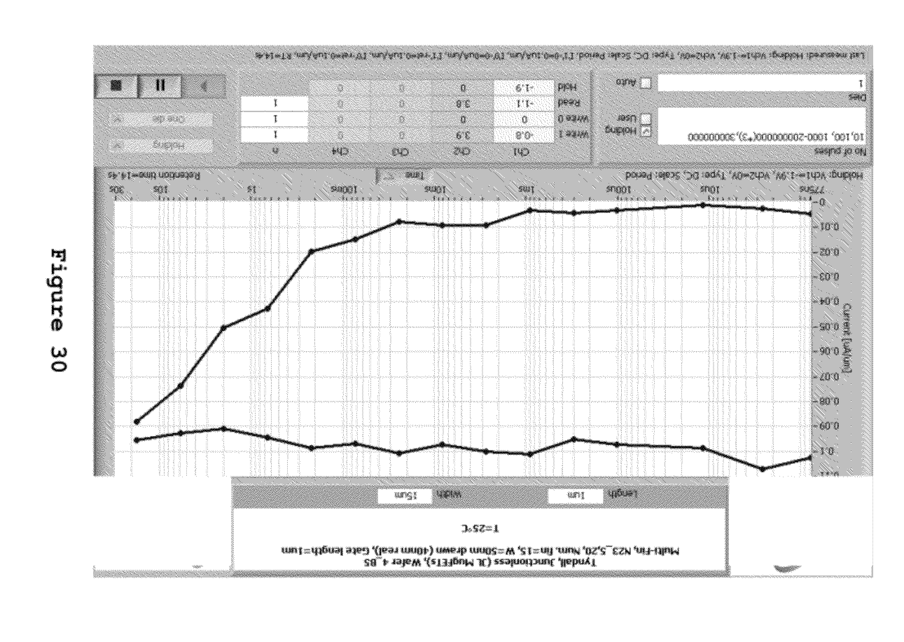

FIG. 29 illustrates the difference between current distribution in an inversion and accumulation mode devices and a junctionless device. In the on state, most of the current flows in channels formed at the semiconductor-gate insulator interface in inversion and accumulation mode devices. In Junctionless devices, it flows in the bulk of the nanowire.

FIG. 30 shows the device tested for capacitor-less memory operation. In this particular test, the junctionless transistor retains information for over 10 seconds which is a very desirable feature. In one embodiment the junctionless transistor of the present invention can be used to fabricate zero-capacitor random-access-memory (ZRAM) cells. Such a device can be programmed to a “0” or “1” logic state and retain the stored information for a finite amount of time. FIG. 30 confirms that the junctionless transistor retains the information for over 10 seconds. By having capacitor-less operation allows for increased performance of the memory device. It is envisaged the junctionless transistor can be used in any Random Access Memory (RAM) device or integrated circuit.

It is worth noting on the sub-threshold slope (SS), since they have the same gate architecture, the conventional trigate MOSFET and the junctionless gated resistor have the same efficiency of electrostatic coupling between the gate potential, V_{G}, and the potential in the channel region in subthreshold operation. As a result, the devices have identical body factor, defined as n≡dV_{G}/DΦ and the same subthreshold slope, which is equal to

$$S S = n \frac{{k}_{B} T}{q} ln ( 10 ) .$$

In an ideal device with perfect coupling between the gate potential and the channel potential, n is equal to unity. In standard bulk MOSFETs the value of n typically ranges between 1.2 and 1.5. Both the trigate MOSFETs and the gated resistors reported here have n≅1.05.

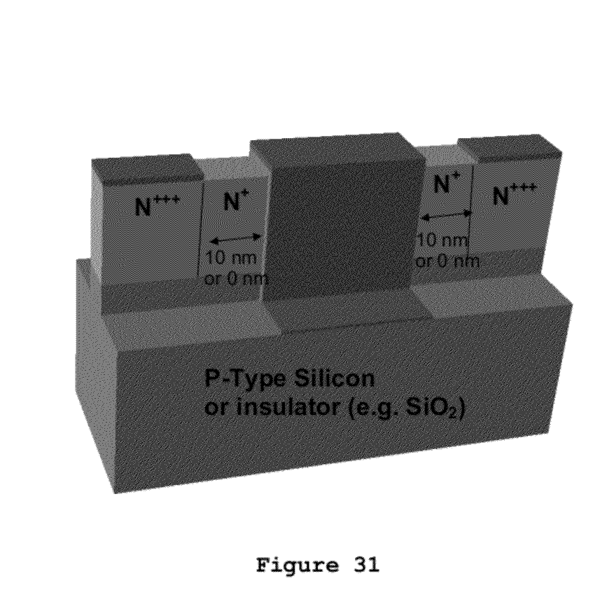

FIG. 31 shows another embodiment of the device according to the invention where the channel is of the same type and with substantially the same doping concentration as the source and drain. If the separation between the gate electrode is separated from the N⁺⁺⁺ source or drain by the indicated 10 nm (or 5 nm, or 2 nm . . . in which case the N⁺⁺⁺ region is outside the region of electrostatic influence of the gate), but not if the separation is 0 nm or if it is a negative value (i.e. if the N⁺⁺⁺ source or drain penetrates underneath the gate electrode). Note that typical values of the N+ doping is 10¹⁹-10²⁰ cm⁻³ and the doping of the N⁺⁺⁺regions is 10²⁰ cm⁻³, so the difference between N⁺ and N⁺⁺⁺ is relatively small i.e. substantially the same.

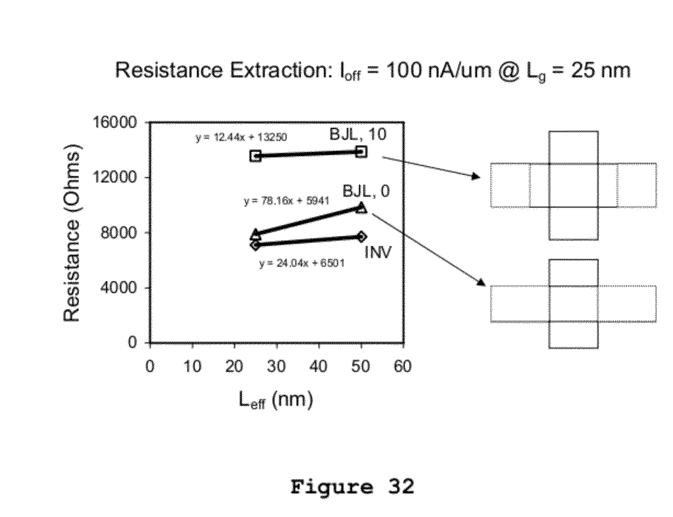

FIG. 32 illustrates simulations that indicate that the N⁺ region between the gate-covered channel region and the N⁺⁺⁺ source or drain have a non-negligible resistance, which reduced the current drive of the device. The graph shows that devices with a 10 -nm N⁺ separation have a series resistance of 13250 ohms, while devices with a 10-nm N⁺ separation have a series resistance of only 5941 ohms (for comparison, the regular inversion-mode device with a source-gate and drain-gate overlap of 4 nm on each side has a resistance of 6501 ohms).

It will be appreciated that the invention can be used for junctionless transistor device using very small geometries Based on first-principles, Si-based transistors are physically possible without major changes in design philosophy at scales of _{—}1 nm wire diameter and _{—}3 nm gate length, according to the invention and that the junctionless transistor avoids potentially serious difficulties affecting junctioned channels at these length scales.

In the context of the present invention, hereinbefore described, the term ‘device’ or ‘circuit’ should be afforded a broad interpretation so along as they comprise a transistor or a plurality of transistors of the invention to make a device or an electronic circuit or a memory circuit or a microprocessor or any computing device.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

What is claimed is:

1. A transistor device comprising a source, a drain and a connecting channel,
the channel is a nano-structure device adapted to allow current flow between the source and drain;
the channel comprises an ultra-high doping concentration and is of the same polarity as in the source and/or drain.

2. The device as claimed in claim 1 wherein the ultra-high doping concentration is equal to or exceeds 1×1019 atom/cm3.

3. The device as claimed in claim 1 wherein the channel is degenerately doped.

4. The device as claimed in claim 1 wherein the ultra-high doping concentration channel is adapted to act like a quasi metallic channel.

5. The device as claimed in claim 1 wherein the nano-structure device is a nano-wire.

6. The device as claimed in claim 1 wherein the device is positioned on a bulk silicon substrate.

7. The device as claimed in claim 1 wherein the device is positioned on a bulk silicon substrate and the device is electrically isolated from the bulk silicon substrate.

8. The device as claimed in claim 7 comprising an insulator layer positioned below the interface between the channel and silicon substrate.

9. The device as claimed in claim 1 wherein the source, the drain and connecting channel comprises a N^{++-N}⁺-N⁺⁺ device to provide a junction-less device.

10. The device as claimed in claim 1 wherein the source, the drain and connecting channel comprises a P⁺⁺-P⁺-P⁺⁺ device to provide a junction-less device.

11. The device as claimed in claim 1 wherein the doping concentration of a selected value can be used in the channel region and the source and drain extension regions.

12. The device as claimed in claim 11 comprising spacer technology adapted to be used to locally increase the outer source and drain regions to a concentration above the selected value.

13. The device as claimed in claim 1 wherein the nano-structure device comprises a planar device.

14. A channel device for use in a transistor to connect a source region and drain region, said channel comprising an ultra-high doping concentration.

15. A multi-gate structure on a bulk silicon substrate comprising a transistor device as claimed in claim 1.

16. A process for making a transistor device comprising the steps of:
arranging one or more nano-device on a substrate, for example a silicon substrate;
implanting ultra high doping concentration in said nano-wire to define a channel region; and
depositing a gate material to cooperate with said one or more nano-wires, said gate material is adapted to control current flow through said channel region by applying a charge to the gate material.

17. The process of claim 16 wherein the ultra-high doping concentration is equal to or exceeds 1×10¹⁹ atom/cm³.

18. A memory device comprising a transistor device, said transistor device comprising a source, a drain and a connecting channel,
the channel is a nano-structure device adapted to allow current flow between the source and drain;
the channel comprises an ultra-high doping concentration and is of the same polarity as in the source and/or drain.
